(19) United States
(12) Patent Application Publication
(10) Pub. No.: US 2026/0143952 A1
(43) Pub. Date: May 21, 2026

(54) DISPLAY APPARATUS AND METHOD OF FABRICATING THEREOF

(71) Applicant: LG Display Co., Ltd., Seoul (KR)

(72) Inventor: Jeong-Kyun SHIN, Paju-si (KR)

(73) Assignee: LG Display Co., Ltd., Seoul (KR)

(21) Appl. No.: 19/328,685

(22) Filed: Sep. 15, 2025

(30) Foreign Application Priority Data
Nov. 20, 2024 (KR) 10-2024-0166059

(51) Int. Cl. H10K 59/80; H10K 59/12; H10K 59/131; H10K 59/95

(52) U.S. Cl. CPC H10K 59/873; H10K 59/1201; H10K 59/131; H10K 59/95

(57) ABSTRACT

A display apparatus according to present disclosure includes a substrate having a display area and a non-display area. A pad electrode is disposed in the non-display area, and an encapsulation layer disposed over both the display area and the non-display area, covering the pad electrode. An opening is formed in the encapsulation layer to expose a portion of the pad electrode to outside. A conductive ball is positioned within the opening, and a data driving unit is mounted above the opening such that it is electrically connected to the pad electrode through the conductive ball. This structure allows for simplified electrical connection without requiring an anisotropic conductive film, thereby reducing manufacturing complexity and cost.

### CROSS-REFERENCE TO RELATED APPLICATIONS

This application claims priority to Korean Patent Application No. 10-2024-0166059, filed in the Republic of Korea on Nov. 20, 2024, the entire contents of which is hereby expressly incorporated by reference into the present application.

### BACKGROUND

### Technical Field

The present disclosure relates to a display apparatus and a manufacturing method thereof capable of reducing manufacturing costs.

### Description of the Related Art

Recently, the importance of flat panel displays apparatus is increasing as the development of multimedia. In response to this, flat panel display apparatus such as a liquid crystal display apparatus, a plasma display apparatus, and an organic light emitting display apparatus are being commercialized. Among the flat panel display apparatus, the organic light emitting display apparatus are currently widely used because it has a high response speed, high brightness, and good viewing angles.

The display apparatus ice includes a plurality of sub-pixels. A thin film transistor and a light emitting device are disposed each of the plurality of sub-pixels. The thin film transistor is turned on by a scan signal applied from a gate driving unit, and a data signal applied from a data driving unit is applied to the light emitting device through the turned-on thin film transistor, thereby displaying an image.

The data driving unit can be provided in various forms. For example, the data driving unit can be manufactured in the form of a chip and then mounted on a flexible circuit board (Chip on Film) or can be directly mounted on the substrate of the display apparatus (Chip on Glass). When the data driving unit is directly mounted on the substrate, the data driving unit is electrically connected to the electrodes of the display apparatus by an anisotropic conductive film (ACF).

However, when the data driving unit is electrically connected to the electrode using ACF, there was a problem that the manufacturing process was complicated and the manufacturing cost increased.

### BRIEF SUMMARY

The disclosed technology provides a simplified and cost-efficient method for electrically connecting a data driving unit to a pad electrode in a display apparatus by eliminating the use of anisotropic conductive films. Conductive balls are dispensed together with an etchant directly onto the encapsulation layer. When heat is applied, the encapsulation material melts to form an opening exposing the pad electrode. As the material dries, it forms an alignment layer made from the same material as the encapsulation layer. Due to differences in evaporation rates across the opening, the alignment layer develops a concave shape that guides the conductive ball to the center, ensuring accurate placement.

This approach enables reliable electrical contact between the conductive ball and the pad electrode while reducing process steps and material consumption. The method integrates etching, ball placement, and alignment into a single operation and is applicable not only to data driving units but also to other integrated circuit connections within electronic devices.

An object of the present disclosure is to provide a display apparatus and a manufacturing method thereof, which can simplify the manufacturing process and reduce manufacturing costs.

In order to achieve the object, a display apparatus according to present disclosure comprises a substrate including a display area and a non-display area, a pad electrode in the non-display area, an encapsulation layer in the display area and the non-display area on the pad electrode, an opening formed in the encapsulation layer to expose a part of the pad electrode to outside, a conductive ball within the opening, and a data driving unit on the opening to be electrically connected to the pad electrode through the conductive ball.

An alignment layer is formed within the opening, and the alignment layer has a concave shape in a central region of the opening so that the conductive ball may be disposed in the central region of the opening. The alignment layer may be formed of the seam material as the encapsulation layer.

A method of fabricating of a display apparatus according to the present disclosure comprises providing a substrate including a display area and a non-display area, forming a pad electrode in the non-display area, forming an encapsulation layer in the display area and the non-display area, dispensing an etchant having conductive balls onto the encapsulation layer over the pad electrode and then melting the encapsulation layer, drying the melted encapsulation layer, and introducing a data driving unit in the non-display area to connect electrically the data driving unit to the pad electrode through the conductive ball.

Melting the encapsulation layer includes applying heat to the encapsulation layer in a vacuum state, and drying the melted encapsulation layer includes forming an alignment layer having a concave shape in a central region of the opening. The conductive ball may move along the inclined surface of the alignment layer so that the conductive ball is disposed in the central region of the opening.

### BRIEF DESCRIPTION OF THE SEVERAL VIEWS OF THE DRAWINGS

FIG. 1 is a schematic block diagram of a display apparatus according to the present disclosure.

FIG. 2 is the schematic block diagram of a sub pixel of a display apparatus according to the present disclosure.

FIG. 3 is a circuit diagram conceptually illustrating the sub pixel of an organic light emitting display apparatus according to the present disclosure.

FIG. 4 is a plan view of the display apparatus according to the present disclosure.

FIG. 5 is a cross-sectional view taken along line I-I′ of FIG. 4.

FIG. 6 is an enlarged cross-sectional view of area A of FIG. 5.

FIGS. 7A to 7D are views showing a method for mounting a data driving unit of an organic light emitting display apparatus according to the present disclosure.

### DETAILED DESCRIPTION

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “comprising,” and the like mentioned in this disclosure are used, other parts may be added unless the term “only” is used herein. When a component is expressed as being singular, being plural is included unless otherwise specified.

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is not used, one or more other parts may be located between the two parts.

In describing a temporal relationship, for example, when a temporal predecessor relationship is described as being “after,” “subsequent,” “next to,” “prior to,” or the like, unless “immediately” or “directly” is not used, cases that are not continuous may also be included.

Although the terms first, second, and the like are used to describe various components, these components are not substantially limited by these terms. These terms are used only to distinguish one component from another component. Therefore, a first component described below may substantially be a second component within the technical spirit of the present disclosure.

In describing the components of the disclosure, terms such as first, second, A, B, (a), (b), etc., may be used. These terms are only for distinguishing the elements from other elements, and the essence, order, or number of the elements is not limited by the terms. When it is described that a component is “connected” “coupled” or “connected” to another component, the component may be directly connected or connected to the other component, but indirectly without specifically stated It should be understood that other components may be “interposed” between each component that is connected or can be connected.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The term “unit” or “module” as used herein may include any electrical circuitry, features, components, an assembly of electronic components, or the like. That is, “unit” or “module” may include any processor-based system including systems using microcontrollers, integrated circuits, chips, microchips, reduced instruction set computers (RISC), application specific integrated circuits (ASICs), field-programmable gate arrays (FPGAs), graphical processing units (GPUs), logic circuits, and any other circuit or processor capable of executing the various operations and functions described herein. The above examples are examples only, and are thus not intended to limit in any way the definition or meaning of the term “unit” or “module.”

In some embodiments, the various units or modules described herein may be included in or otherwise implemented by processing circuitry such as a microprocessor, microcontroller, or the like.

As used herein, the term “apparatus” may include a display apparatus such as a liquid crystal module (LCM) including a display panel and a driving unit for driving the display panel, and an organic light emitting display module (OLED module). Further, the term “apparatus” may further include a notebook computer, a television, a computer monitor, a vehicle electric apparatus including an apparatus for a vehicle or other type of vehicle, and a set electronic apparatus or a set apparatus such as a mobile electronic apparatus of a smart phone or an electronic pad, etc., which are a finished product (complete product or final product) including LCM and OLED module.

Accordingly, the apparatus in the disclosure may include the display apparatus itself such as the LCM, the OLED module, etc., and the application product including the LCM, the OLED module, or the like, or the set apparatus, which is the apparatus for end users.

Hereinafter, the present disclosure will be described in detail with reference to the accompanying drawings.

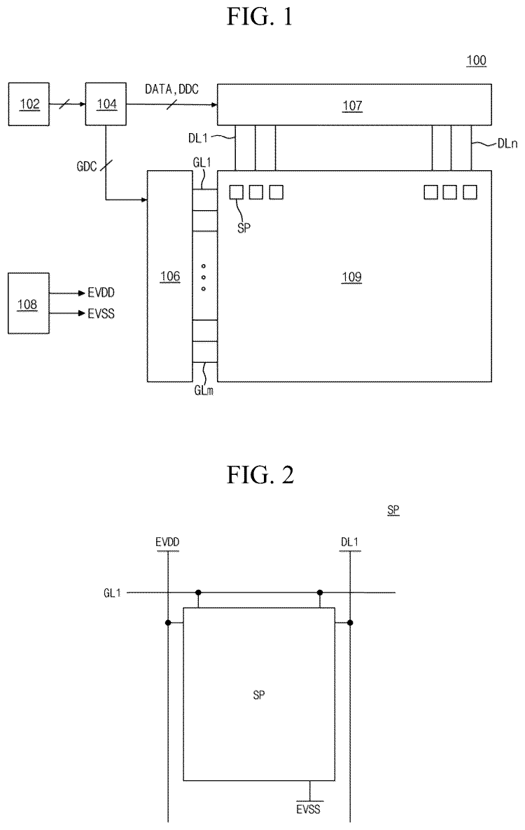

FIG. 1 is the schematic block diagram and FIG. 2 is the schematic block diagram of the sub-pixel of the organic light emitting display apparatus according to the present disclosure.

As shown in FIG. 1, the organic light emitting display apparatus 100 includes an image processing unit 102, a timing controlling unit 104, a gate driving unit 106, a data driving unit 107, a power supplying unit 108, and a display panel 109.

The image processing unit 102 outputs an image data supplied from outside and a driving signal for driving various devices. For example, the driving signal from the image processing unit 102 can include a data enable signal, a vertical synchronizing signal, a horizontal synchronizing signal, and a clock signal.

The image data and the driving signal are supplied to the timing controlling unit 104 from the image processing unit 102. The timing controlling unit 104 writes and outputs gate timing controlling signal GDC for controlling the driving timing of the gate driving unit 106 and data timing controlling signal DDC for controlling the driving timing of the data driving unit 107 based on the driving signal from the image processing unit 102.

The gate driving unit 106 outputs the scan signal to the display panel 109 in response to the gate timing control signal GDC supplied from the timing controlling unit 104. The gate driving unit 106 outputs the scan signal through a plurality of gate lines GL1 to GLm. In this case, the gate driving unit 106 may be formed in the form of an integrated circuit (IC), but is not limited thereto. The gate driving unit 106 includes various gate driving circuits, and the gate driving circuit can be formed directly on the substrate of the display panel 109. In this case, the gate driving unit 106 can be a GIP (Gate-In-Panel).

The data driving unit 107 outputs the data voltage to the display panel 109 in response to the data timing control signal DDC input from the timing controlling unit 104. The data driving unit 107 samples and latches the digital data signal DATA supplied from the timing controlling unit 104 to convert it into the analog data voltage based on the gamma voltage. The data driving unit 107 outputs the data voltage through the plurality of data lines DL1 to DLn. In this case, the data driving 107 may be mounted on the upper surface of the display panel 109 in the form of an integrated circuit (IC), but is limited thereto.

The power supplying unit 108 outputs a high potential voltage VDD and a low potential voltage VSS, etc., to supply these to the display panel 109. The high potential voltage VDD is supplied to the display panel 109 through the first power line EVDD and the low potential voltage VSS is supplied to the display panel 109 through the second power line EVSS. In this time, the voltage from the power supplying unit 108 are applied to the data driving unit 107 or the gate driving unit 106 to drive thereto.

The display panel 109 displays the image based on the data voltage from the data driving unit 107, the scan signal from the gate driving unit 106, and the power from the power supplying unit 108.

The display panel 109 includes a plurality of sub-pixels SP to display the image. The sub-pixel SP can include Red sub-pixel, Green sub-pixel, and Blue sub-pixel. Further, the sub-pixel SP can include White sub-pixel, the Red sub-pixel, the Green sub-pixel, and the Blue sub-pixel. The White sub-pixel, the Red sub-pixel, the Green sub-pixel, and the Blue sub-pixel may be formed in the same area or may be formed in different areas.

As shown in FIG. 2, one sub-pixel SP may be connected to the gate line GL1, the data line DL1, the first power line EVDD, and the second power line EVSS. The sub-pixel SP may include a plurality of thin film transistors and a storage capacitor depending on the configuration of the pixel circuit. For example, the sub-pixel SP may include two transistors and one capacitor (2T1C), but is not limited thereto, and the sub-pixel SP may be composed of 3T1C, 4T1C, 5T1C, 6T1C, 7T1C, 3T2C, 4T2C, 5T2C, 6T2C, 7T2C, 8T2C, etc.

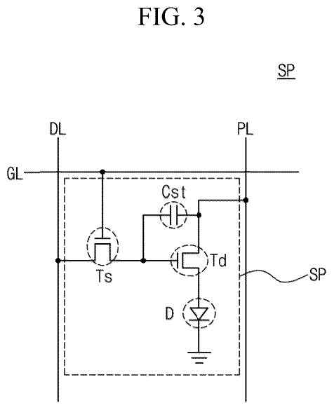

FIG. 3 is the circuit diagram illustrating the sub-pixel SP of the organic light emitting display apparatus 100 according to the present disclosure.

As shown in FIG. 3, the organic light emitting display apparatus 100 according to the present disclosure includes the gate line GL, the data line DL, and the power line PL crossing each other for defining the sub-pixel SP. A switching thin film transistor Ts, a driving thin film transistor Td, a storage capacitor Cst, and an organic light emitting device D are disposed in the sub-pixel SP.

The switching thin film transistor Ts is connected to the gate line GL and the data line DL, and the driving thin film transistor Td and the storage capacitor Cst are connected between the switching thin film transistor Ts and the power line PL. The organic light emitting device D is connected to the driving thin film transistor Td.

In the organic light emitting display apparatus having this structure, when the switching thin film transistor Ts is turned on according to the gate signal applied to the gate line GL, the data signal applied to the data line DL is applied to the gate electrode of the driving thin film transistor Td and one electrode of the storage capacitor Cst through the switching thin film transistor Ts.

The driving thin film transistor Td is turned on according to the data signal applied to the gate electrode. As a result, the current proportional to the data signal is supplied to the organic light emitting device D from the power line PL through the driving thin film transistor Td and then the organic light emitting device D emits light with a luminance proportional to the current flowing through the driving thin film transistor Td.

At this time, the storage capacitor Cst is charged with the voltage proportional to the data signal to keep the voltage of the gate electrode of the driving thin film transistor Td constant for one frame.

In the figure, only two thin film transistors Td and Ts and one capacitor Cst are provided, but the present disclosure is not limited thereto. Three or more thin film transistors and two or more capacitors may be provided in the present disclosure.

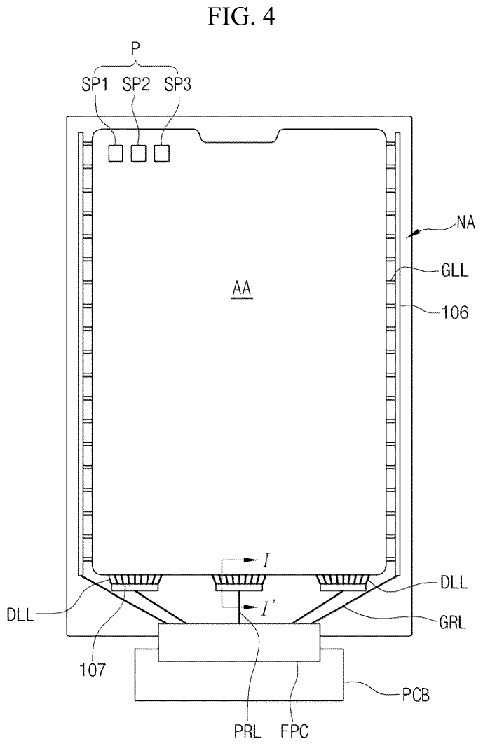

FIG. 4 is a plan view schematically showing the structure of the display apparatus 100 according to the present disclosure.

As shown in FIG. 4, the display apparatus 100 according to the present disclosure includes a display area AA where an actual image is displayed and a non-display area NA outside the display area AA.

A pixel P including a plurality of sub-pixels SP1, SP2, and SP3 is arranged in the display area AA. At this time, each of the sub-pixels SP1, SP2, and SP3 may include a red (R) sub-pixel, a green (G) sub-pixel, and a blue (B) sub-pixel. In addition, the pixel P may further include a white (W) sub-pixel.

Although not shown in the figure, a plurality of gate lines and data lines are arranged in the display area AA to define a plurality of sub-pixels SP in the intersection area of the gate lines and data lines. In each sub-pixel SP1, SP2, and SP3, a thin film transistor as a switching device and a display device for displaying an image are arranged.

The display device may include various display devices. For example, the display device may be an organic light emitting display device, a liquid crystal display device, a quantum dot display device, a micro LED display device, or a mini LED display device.

The gate driving unit 106 and the data driving unit 107 for supplying various signals to sub-pixels SP1, SP2, and SP3 can be disposed in the non-display area NA. The gate driving unit 106 applies the scan signal to the sub-pixels SP1, SP2, and SP3 through the gate line, and the data driving unit 107 applies the image signal to the sub-pixels SP1, SP2, and SP3 through the data line.

The gate driving unit 106 may be a GIP (Gate In Panel) circuit in which a driving circuit is directly integrated on the substrate. The gate driving unit 106 is connected to the gate line of the display area AA through the gate link line GLL to apply the scan signal. In the figure, the gate driving unit 106 is arranged in the non-display area NA in both sides of the display area AA, but the gate driving unit 106 may be arranged only in the non-display area NA in one side of the display area AA.

The data driving unit 107 is disposed in the non-display area NA below the display area AA. The data driving unit 107 includes a plurality of IC chips and is mounted on the substrate. The data driving unit 107 is connected to the data line of the display area AA through a data link line DLL to apply the data signal.

One end of a flexible circuit board FPC is attached to end of the non-display area NA below the display area AA, and a printed circuit board PCB is attached to the other end of the flexible circuit board FPC. A plurality of signal lines are arranged on the flexible circuit board FPC, and the timing controlling unit and the power supplying unit are disposed on the printed circuit board PCB. A gate routing line GRL and a data routing line DRL are disposed at the bottom of the non-display area NA below the display area AA to electrically connect the signal line of the flexible circuit board FPC to the gate driving unit 106 and the data driving unit 107.

The control signal and the voltage supplied respectively from the timing controlling unit and power supplying unit of the printed circuit board PCB are applied to the gate driving unit 106 and the data driving unit 107 through the signal lines, the gate routing lines GRL, and the data routing lines DRL.

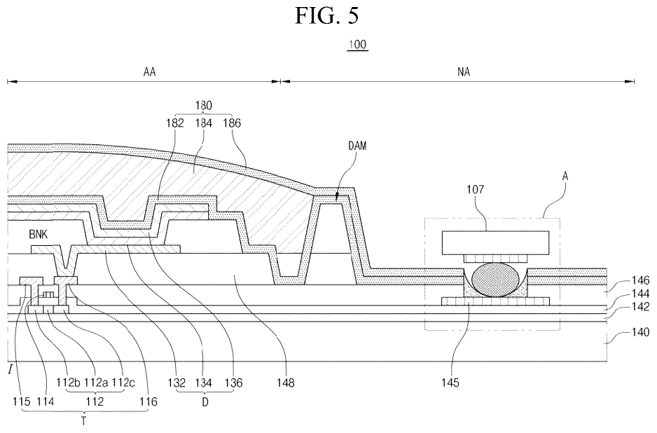

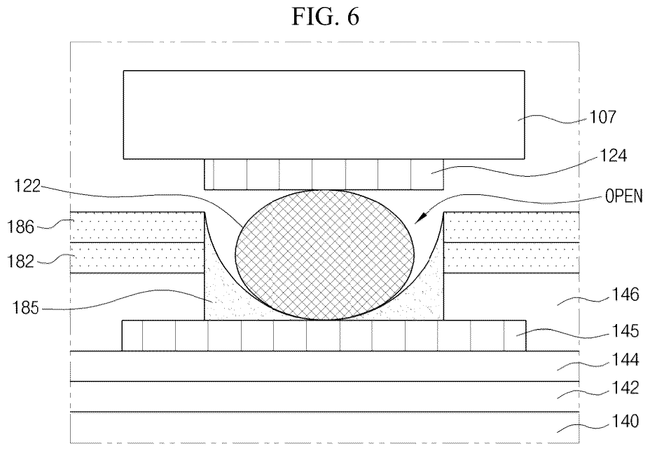

FIG. 5 is a cross-sectional view taken along line I-I′ of FIG. 4, which specifically illustrates the structure of the display apparatus 100 according to the present disclosure. FIG. 6 is an enlarged cross-sectional view of area A of FIG. 5.

As shown in FIGS. 5 and 6, the substrate 140 includes the display area AA and the non-display area NA. The substrate 140 may be made of a hard material such as a glass or a flexible plastic material.

If the substrate 140 is made of the plastic material, the plastic material may include a polyimide, a polymethylmethacrylate, a polyethylene tereththalate, a Polyethersulfone, and a Polycarbonate.

When the substrate 140 is made of polyimide, the substrate 140 may be made of a plurality of polyimide layers, and an inorganic layer may be further disposed between the polyimide layers, but is not limited thereto.

A buffer layer 142 is formed on the substrate 140. The buffer layer 142 may be formed in the entire area of the substrate 140 to enhance adhering force between the substrate 140 and the layers thereon. Further, the buffer layer 142 may block various types of defects, such as alkali components flowing out from the substrate 140. In addition, the buffer layer 142 may delay diffusion of moisture or oxygen penetrating into the substrate 140.

The buffer layer 142 may be a single layer made of silicon oxide (SiOx) or silicon nitride (SiNx), or multi-layers thereof. When the buffer layer 142 is made of multiple layers, SiOx and SiNx may be alternately formed. The buffer layer 142 may be omitted based on the type and material of the substrate 140, the structure and type of the thin film transistor, and the like.

A thin film transistor T is formed on the buffer layer 142 in each sub-pixel. For convenience of description, only the driving thin film transistor among various thin film transistors that may be disposed in the display area AA is illustrated, but other thin film transistors such as switching thin film transistors may also be included. In the figure, the thin film transistor of a top gate structure is shown, but the thin film transistor is not limited to this structure and may be formed in other structures such as the thin film transistor of a bottom gate structure.

The thin film transistor T includes a semiconductor pattern 112 disposed on the buffer layer 142, a gate insulating layer 144 covering the semiconductor pattern 112, a gate electrode 114 on the gate insulating layer 144, an interlayer insulating layer 146 covering the gate electrode 114, and a source electrode 115 and a drain electrode 116 on the interlayer insulating layer 146.

The semiconductor pattern 112 may be made of a polycrystalline semiconductor. For example, the polycrystalline semiconductor may be made of low temperature poly silicon (LTPS) having high mobility, but is not limited thereto.

The semiconductor pattern 112 may be made of an oxide semiconductor. For example, semiconductor pattern 112 may be made of one of IGZO (Indium-gallium-zinc-oxide), IZO (Indium-zinc-oxide), IGTO (Indium-gallium-tin-oxide), and IGO (Indium-gallium-oxide), but is not limited thereto. The semiconductor pattern 112 includes a channel region 112a in a central region and a source region 112b and a drain region 112c which are doped layers at the both sides of the channel region 112a.

The gate insulating layer 144 may be formed in the entire area of the substrate 140 or formed only in a part area of the substrate 140. The gate insulating layer 144 may be composed of a single layer or multiple layers made of an inorganic material such as SiOx or SiNx, but is not limited thereto.

The gate electrode 114 is made of a metal. For example, the gate electrode 114 may be formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto.

The interlayer insulating layer 146 may be made of the organic material such as photo-acryl, or the interlayer insulating layer 146 may formed of the single layer or the multiple layers made of the inorganic material such as SiOx or SiNx, but is not limited thereto. Further, the interlayer insulating layer 146 may be formed of the multi layers of the organic material layer and the inorganic material layer, but is not limited thereto.

The source electrode 115 and the drain electrode 116 are formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto. The source electrode 115 and the drain electrode 116 may be respectively contacted to the source region 112b and the drain region 112c of the semiconductor pattern 112 through contact holes formed in the gate insulating layer 144 and the interlayer insulating layer 146.

Although not shown in figure, a bottom shield metal layer may be disposed on the substrate 140 under the semiconductor pattern 112. The bottom shield metal layer minimizes a backchannel phenomenon caused by charges trapped in the substrate 140 to prevent afterimages or deterioration of transistor performance. The bottom shield metal layer may be composed of the single layer or the multi layers made of titanium (Ti), molybdenum (Mo), or an alloy thereof, but is not limited thereto.

A planarization layer 148 is formed on the substrate where the thin film transistor is disposed. The planarization layer 148 may be formed of the organic material such as photoacrylic. But it is not limited thereto. The planarization layer 148 may include a plurality of layers including the inorganic layer and the organic layer.

A light emitting device D is disposed in each sub-pixel on the planarization layer 148. The light emitting device D includes a first electrode 132, a light emitting layer 134, and a second electrode 136.

The first electrode 132 is disposed on the planarization layer 148 and electrically connected to the drain electrode 116 of the thin film transistor T through the contact hole formed in the planarization layer 148. The first electrode 132 may be formed of at least one of silver (Ag), aluminum (Al), gold (Au), molybdenum (Mo), tungsten (W), chromium (Cr), or an alloy thereof. Further, the first electrode 132 may be formed of a transparent metal oxide material such as indium tin oxide (ITO) or indium zinc oxide (IZO).

When the display apparatus 100 is a top emission type display apparatus, the first electrode 132 may further include an opaque conductive material layer to function as a reflective electrode that reflects light. When the display apparatus 100 is a bottom emission type display apparatus, the first electrode 132 may be made of the transparent conductive material such as ITO or IZO.

A bank layer BNK is formed at the boundary between the sub-pixels on the planarization layer 148. The bank layer BNK may be a barrier wall to define sub-pixels. The bank layer BNK divides each sub-pixel to prevent light of a specific color output from adjacent sub-pixels from being mixed and output.

The bank layer BNK is made of at least one material of the inorganic insulating material such as SiNx or SiOx, the organic insulating material such as Benzo Cyclo Butene, acrylic resin, epoxy resin, phenolic resin, polyamide resin, or the photosensitizer including black pigment, but is not limited thereto.

The light emitting layer 134 is formed on the upper surface of the first electrode 132, the inclined surface of the bank layer BNK, and a portion of the upper surface of the bank layer BNK of the display area AA, and may extend to the non-display area NA.

The light emitting layer 134 may be formed in R, G, and B sub-pixels and include an R-light emitting layer for emitting red light, a G-light emitting layer for emitting green light, and a B-light emitting layer for emitting blue light. For example, the light emitting layer 134 may be the organic light emitting layer, an inorganic light emitting layer, a nano-sized material layer, a quantum dot layer, a micro LED light emitting layer, or a mini LED light emitting layer, but is not limited thereto.

The light emitting layer 134 may further include an electron injecting layer for injecting electrons into the light emitting layer, a hole injecting layer for injecting holes into the light emitting layer, an electron transporting layer for transporting the injected electrons to the light emitting layer, a hole transporting layer for transporting the injected holes to the light emitting layer, an electron blocking layer, and a hole blocking layer, but is not limited thereto.

The second electrode 136 is disposed on the light emitting layer 134 and may be formed of the single layer or the multi layers made of the metal or the alloy thereof. Further, the second electrode 136 may be made of the transparent metal oxide material such as ITO or IZO, but is not limited thereto.

When the display apparatus 100 is the top emission type, the second electrode 136 may be made of the half-transparent conductive material that transmits light. For example, the second electrode 136 may be made of at least one or more of the alloys such as LiF/Al, CsF/Al, Mg:Ag, Ca/Ag, Ca:Ag, LiF/Mg:Ag, LiF/Ca/Ag, or LiF/Ca:Ag.

When the display apparatus 100 is the bottom emission type, the second electrode 136 may be the reflective electrode made of the opaque conductive material. For example, the second electrode 136 may be made of at least one or more of silver (Ag), aluminum (Al), gold (Au), molybdenum (Mo), tungsten (W), chromium (Cr), or alloys thereof.

Further, the light emitting device D may be formed in a tandem structure. The tandem structure may include a plurality of organic light emitting layers and a charge generating layer disposed between the organic light emitting layers. The charge generating layer is disposed to adjust the charge balance between the plurality of organic light emitting layers, and may be formed of a plurality of layers including a first charge generating layer and a second charge generating layer. The charge generating layer may include an N-type charge generating layer and a P-type charge generating layer. In this case, the charge generating layer may be formed of the organic layer doped with an alkali metal such as Li, Na, K, or Cs or an alkaline earth metal such as Mg, Sr, Ba, or Ra, but is not limited thereto.

An encapsulation layer 180 is formed in the display area AA and the non-display area NA to encapsulate the light emitting device D. When the light emitting device D is exposed to impurities such as moisture or oxygen, a pixel shrinkage phenomenon in which the light emitting area is reduced or the defect such as a dark spot in the light emitting area may occur. Further, moisture or oxygen penetrating the light emitting device D oxidizes the metal electrode. The encapsulation layer 180 blocks impurities such as oxygen and moisture from the outside to prevent defects of the light emitting device D and various electrodes.

The encapsulation layer 180 may be formed of a first encapsulation layers 182a, a second encapsulation layer 184, and a third encapsulation layer 186, but is not limited thereto. The encapsulation layer 180 may be formed of two layers or four or more layers.

The first encapsulation layer 182 and the third encapsulation layer 186 may be made of the inorganic material such as SiOx or SiNx, but are not limited thereto. The second encapsulation layer 184 may be made of the organic insulating material such as acrylic resin, epoxy resin, polyimide, polyethylene, or silicon oxy carbon (SiOC), but is not limited thereto. Further, the third encapsulation layer 186 may be made of thin metal (Face Seal Metal), but is not limited thereto.

Although not shown in figure, a touch member may be disposed on the encapsulating layer 180. The touch member can detect external touch information using the user's finger or a touch pen.

A dam DAM is formed in the non-display area NA. Since the organic material forming the second encapsulation layer 184 has fluidity, the organic material may flow out to the outside of the substrate 140 by the fluidity when the second encapsulation layer 184 is formed. Since the dam DAM is formed to surround the display area AA, the organic materials flowing out of the substrate 140 may be contained by the dam DAM when the second encapsulation layer 184 is formed. Therefore, the organic material does not flow out of the substrate 140. In the figure, although only one dam DAM is shown, the multiple dams DAM may be disposed.

The dam DAM may be formed of the multiple layers. For example, the dam DAM may be formed of two layers made of the same material as the planarization layer 148 and the bank layer BNK. However, the dam DAM of the present disclosure is not limited thereto and may be formed of the single layer or three or more layers.

A pad electrode 145 is disposed on the gate insulating layer 144 in the non-display area NA. The pad electrode 145 may include a first pad electrode connected to the data routing line to receive the signal from the flexible circuit board, and a second pad electrode connected to the data link line to supply the signal to the display area. However, only one pad electrode is shown in the figure for convenience of explanation.

The interlayer insulating layer 146 is disposed on the pad electrode 145, and a part of the interlayer insulating layer 146 over the pad electrode 145 is removed to form an opening OPEN in which a portion of the pad electrode 145 is exposed to the outside. The first encapsulating layer 182 and the third encapsulating layer 186 are disposed on the interlayer insulating layer 146 of the non-display area NA. At this time, when the interlayer insulating layer 146 over the pad electrode 145 is removed, the first encapsulating layer 182 and the third encapsulating layer 186 are also removed.

An alignment layer 185 is formed within the opening OPEN, and a conductive ball 122 is disposed within the opening OPEN. The conductive ball 122 within the opening OPEN is placed at the predetermined position by the alignment layer 185. The alignment layer 185 may be formed of the insulating layer having a certain slope from the center to the edge of the opening OPEN. That is, the thickness of the alignment layer 185 is increased toward from the center to the edge of the opening OPEN, so that the alignment layer 185 may be formed in an infundibular shape that the center of the opening OPEN is concave.

Therefore, when the conductive ball 122 is disposed within the opening OPEN, the conductive ball 122 can always be disposed in the center of the opening OPEN due to the infundibular shape of the alignment layer 185.

The alignment layer 185 may be made of the same material as the interlayer insulating layer 146, the first encapsulation layer 182, and/or the third encapsulation layer 186. As will be described in detail later, the alignment layer 185 may be a film that is hardened after the interlayer insulating layer 146, the first encapsulation layer 182, and/or the third encapsulation layer 186 are melted.

The data driving unit 107 is disposed on the upper part of the opening OPEN. The data driving unit 107 is an IC chip having a bump 124 at the lower surface thereof. Since the bump 124 is contacted with the conductive ball 122, the pad electrode 145 and the data driving unit 107 are electrically connected to each other by the conductive ball 124.

The bump 124 may include an input bump and an output bump. The input bump is connected to the pad electrode 145 (strictly speaking, the first pad electrode) connected to the data routing line through the conductive ball 122 to input the control signal to the data driving unit 107 from the timing control unit. The output bump is connected to a pad electrode 145 (strictly speaking, a second pad electrode) connected to the data link line through the conductive ball 122 to supply the data signal to the data line.

In FIG. 5, the data driving unit 107 is spaced apart from the third encapsulation layer 186 by a certain distance, but this is for convenience of explanation. Although not shown in the figure, the data driving unit 107 may be attached to the upper surface of the third encapsulation layer 186 by an adhesive member.

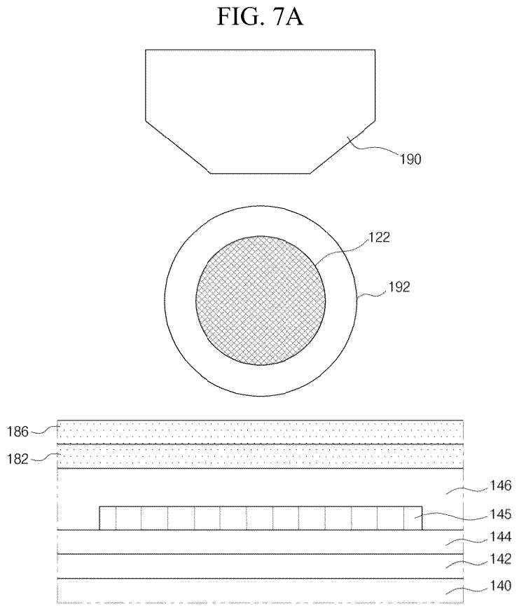

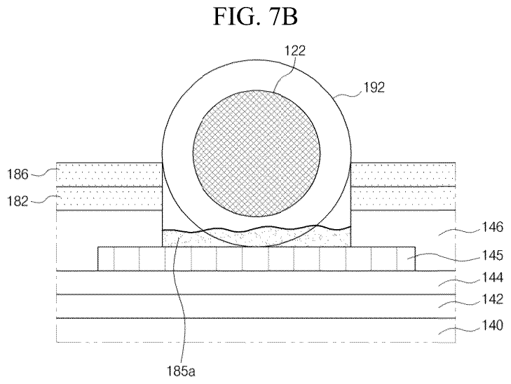

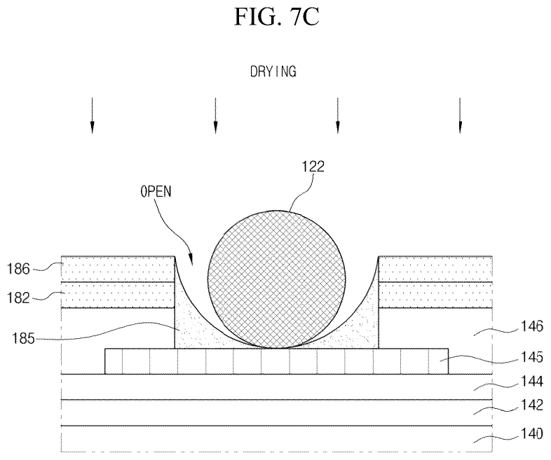

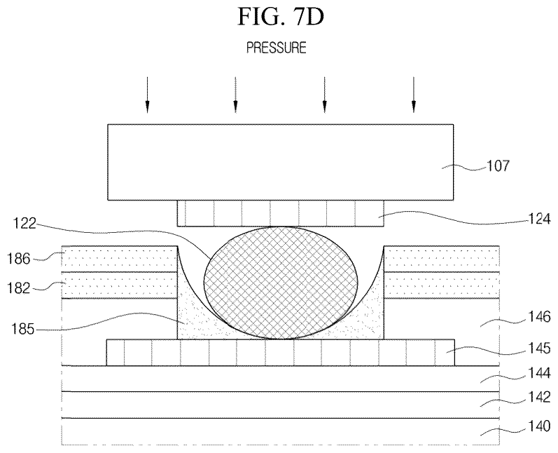

FIGS. 7A to 7D are drawings showing the method of mounting the data driving unit 107 of the display apparatus 100 according to the present disclosure.

First, as shown in FIG. 7A, the thin film transistor and the light emitting device are formed in each sub-pixel of the substrate including the display area AA and the non-display area NA, and then the pad electrode 145 and the dam DAM are formed in the non-display area NA.

Thereafter, after forming the encapsulation layer including the first to third encapsulation layers over the entire substrate, a dispenser 190 is placed on the third encapsulation layer 186 of the non-display area NA to dispense etchant 192 on the third encapsulation layer 186 above the pad electrode 145. The etchant 192 may include a plurality of conductive balls 122 to be dispensed together when the etchant 192 is dispensed.

As shown in FIG. 7B, when the etchant 192 is dispensed, the interlayer insulating layer 146, the first encapsulation layer 182, and the third encapsulation layer 186 over the pad electrode 145 are melted. At this time, a portion of the melted encapsulation material is vaporized and removed, and the remainder 185a remains on the upper surface of the pad electrode 145 in a molten state.

Subsequently as shown in FIG. 7C, when the heat is applied to the display apparatus to dry thereto in a vacuum state, the etchant 192 is removed by the vaporization, and the opening OPEN is formed in the interlayer insulating layer 146, the first encapsulation layer 182, and the third encapsulation layer 186 in which a portion of the surface of the pad electrode 145 is exposed to the outside. At the same time, the encapsulation material that was melted and remained on the pad electrode 145 is dried, so that the alignment layer 185 is formed on the upper surface of the pad electrode 145.

Since the alignment layer 185 is formed by drying the molten inorganic encapsulation material, the alignment layer 185 is made of the same material as the first encapsulation layer 182 and the third encapsulation layer 186. Further, the alignment layer 185 may be made of the same material as the interlayer insulating layer 146.

The alignment layer 185 may be formed in the shape in which the thickness is increased from the center in the outside of the opening OPEN, that is, in the shape in which the center is concave. The reason why the thickness of the dried alignment layer 185 is increased from the center to the outside in the opening OPEN is as follows.

When the molten inorganic encapsulation material is dried, the etchant is evaporated and then removed. At this time, the evaporation rate of the etchant varies depending on the location of the opening OPEN. For example, when the evaporation of the etchant begins, the vaporized etchant exists above the opening OPEN. At this time, the amount of the etchant vaporized at the central region of the opening OPEN is greater than the amount of the etchant vaporized at the edge of the opening OPEN (i.e., the area adjacent to the area where the etchant does not exist).

The density of the vaporized etchant is greatest in the upper region of the central region of the opening OPEN and decreases toward the edge. The drying speed of the encapsulation material is related to the density of the vaporized etchant in the upper region of the opening OPEN. For example, the drying speed of the encapsulation material in the central region of the opening OPEN may be lowest and the drying speed of the etchant may increase toward the edge.

Accordingly, since the evaporation rate of the encapsulation material in the central region of the opening OPEN is the greatest, the encapsulation material in the edge of the opening OPEN is dried first. Accordingly, some of the undried encapsulation material in the central region spreads to the edge region, and the thickness is increased from the central region to the edge region, so that the alignment layer 185 in the opening OPEN is formed in concave central region.

As the encapsulation material dries, the conductive ball 122 dispensed in the opening OPEN moves along the inclined surface of the alignment layer 185 to the central area of the opening OPEN. Although one conductive ball 122 is disclosed in the figure, a plurality of conductive balls 142 may be placed in the central area of the opening OPEN.

After that, as shown in FIG. 7D, the data driving unit 107 is disposed on the upper part of the opening OPEN, and then pressured to mount the data driving unit 107 on the display apparatus. At this time, the bump 124 and pad electrode 145 of the data driving unit 107 are electrically connected to the conductive ball 122.

As described above, in the display apparatus according to the present disclosure, the conductive balls are included in the etching solution and the conductive balls are disposed within the opening on the pad electrode at the same time as the opening is formed, so that there is no need to use an anisotropic conductive film in which conductive balls are dispersed within a resin layer, thereby simplifying the manufacturing process.

Further, since the conductive balls are disposed only the upper portion of the pad electrode in the present disclosure, the manufacturing cost can be significantly reduced compared to using the conductive film in which the conductive balls are dispersed throughout the entire film.

Meanwhile, although the above description mainly describes the connection structure between the data driving unit and the pad electrode, the present disclosure is not limited to this structure. For example, the present disclosure can be applied to the connection structure between the gate driving unit in the form of an IC chip and the pad electrode. Further, the present disclosure can be applied to the electrical connection structure of various electronic devices that connect the bumps of IC chip and pad electrode.

The above description and the accompanying drawings are merely illustrative of the technical spirit of the present disclosure, and those of ordinary skill in the art to which the present disclosure pertains can combine configurations within a range that does not depart from the essential characteristics of the present disclosure, various modifications or variations such as separation, substitution and alteration will be possible. Therefore, the embodiments disclosed in the present disclosure are not intended to limit the technical spirit of the present disclosure, but to explain, and the scope of the technical spirit of the present disclosure is not limited by these embodiments.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate including a display area and a non-display area;
a pad electrode in the non-display area;
an encapsulation layer is over both the display area and the non-display area and over the pad electrode located in the non-display area;
an opening extending through the encapsulation layer;
a conductive ball within the opening; and
a data driving circuit over the opening and electrically connected to the pad electrode through the conductive ball.

2. The display apparatus of claim 1, further comprising an alignment layer within the opening.

3. The display apparatus of claim 2, wherein the alignment layer has a concave shape in a central region of the opening to position the conductive ball in the central region of the opening.

4. The display apparatus of claim 3, wherein the conductive ball is guided along the inclined surface of the alignment layer to be disposed in the central region of the opening.

5. The display apparatus of claim 3, wherein the alignment layer is formed of the same material as the encapsulation layer.

6. The display apparatus of claim 5, wherein the alignment layer is formed by melting and then drying the encapsulation layer.

7. A method of fabricating a display apparatus, comprising:
providing a substrate including a display area and a non-display area;
forming a pad electrode in the non-display area;
forming an encapsulation layer in the display area and the non-display area;
dispensing an etchant having conductive balls onto the encapsulation layer over the pad electrode and then melting the encapsulation layer;
drying the melted encapsulation layer; and
introducing a data driving circuit in the non-display area to electrically connect the data driving circuit to the pad electrode through the conductive ball.

8. The method of claim 7, wherein melting the encapsulation layer includes applying heat to the encapsulation layer in a vacuum state.

9. The method of claim 7, wherein drying the melted encapsulation layer includes forming an alignment layer having a concave shape in a central region of the opening.

10. The method of claim 9, wherein the conductive ball moves along the inclined surface of the alignment layer so that the conductive ball is disposed in the central region of the opening.

11. A connection structure of a pad, comprising:
a pad electrode;
at least one insulating layer over the pad electrode;
an opening extending through the insulating layer;
an alignment layer within the opening, the alignment layer including a concave inclined surface in a central region of the opening;
a conductive ball over the pad electrode in the central region of the alignment layer; and
a bump connected electrically to the pad electrode through the conductive ball.

12. The connection structure of claim 11, wherein the alignment layer is formed of the same material as the insulating layer.

13. The connection structure of claim 11, wherein the conductive ball is guided along the inclined surface of the alignment layer to be disposed in the central region of the opening.

14. The connection structure of claim 11, wherein the bump is formed in an IC chip.

15. The connection structure of claim 14, wherein the IC chip includes a data driving circuit.

16. The connection structure of claim 14, wherein the IC chip includes a gate driving circuit.

17. The display apparatus of claim 1, wherein a single conductive ball is disposed within each opening.

18. The display apparatus of claim 1, further comprising ad adhesive member,
wherein the data driving circuit is adhered to an upper surface of the encapsulation layer using the adhesive member.
